(19) United States
(12) Patent Application Publication
(10) Pub. No.: US 2015/0184887 A1
(43) Pub. Date: Jul. 2, 2015

(54) ELECTRICAL INTERCONNECT AND METHOD

(71) Applicant: Save The World Air, Inc., Santa Barbara, CA (US)

(72) Inventors: Carl D. Meinhart, Santa Barbara, CA (US); Bjorn D. H. Simundson, Santa Barbara, CA (US)

(21) Appl. No.: 14/581,442

(22) Filed: Dec. 23, 2014

Related U.S. Application Data
(60) Provisional application No. 61/920,879, filed on Dec. 26, 2013.

(51) Int. Cl. F24H 1/00; H05K 13/04; H05B 3/06

(52) U.S. Cl. CPC F24H 1/0018; H05B 3/06; H05K 13/04

(57) ABSTRACT

An apparatus for transmitting an electrical current through a treating vessel. The vessel may be under pressure. The treating vessel contains a series of electrically charged plates. An internal portion of the treating vessel contains a hydrocarbon liquid. The apparatus includes a housing having an inner portion, an electrical shaft positioned within the housing, and an insulated body casted within the inner portion of the housing. The electrode shaft is embedded within the insulated body. The insulated body may be formed of a polyurethane material.

### CROSS-REFERENCE TO RELATED INVENTIONS

This application claims the benefit of and priority to U.S. Provisional Patent Application No. 61/920,879, filed on Dec. 26, 2013, which is incorporated by reference herein.

### BACKGROUND OF THE INVENTION

This invention relates to an electrical interconnect used with a vessel. More specifically, but not by way of limitation, this invention relates to an electrical interconnect used with a treating vessel containing a hydrocarbon liquid and electrically charged plates.

Various devices and methods have been used to deliver an electrical current to a treating vessel. In certain situations, a treating vessel has been used to lower the viscosity of a hydrocarbon liquid, such as crude oil. In these situations, the treating vessel may contain a series of charged electrical plates. The hydrocarbon liquid is flowed through the treating vessel, and in particular, through the treating plates which in turn lowers the viscosity. Prior art treating vessels are commercially available from STWA, Inc. under the name AOT.

### SUMMARY OF THE INVENTION

In one embodiment, an apparatus for transmitting an electrical current through a vessel is disclosed. The vessel has a series of electrically charged plates within an internal portion. The vessel is under a pressure and contains a hydrocarbon liquid within the internal portion. The apparatus includes: a first housing having an inner portion operatively associated with the vessel, a first electrical interconnect shaft positioned within the first housing, and a first insulated body casted within an inner portion of the first housing, wherein the first electrical interconnect shaft being embedded within the first insulated body, and wherein the first insulated body includes a polyurethane material. The apparatus may further include: a second housing having an inner portion operatively associated with the vessel; and a second electrical interconnect shaft positioned within the second housing, with the first insulated body casted within the inner portion of the second housing and encapsulating the second electrical interconnect shaft, wherein the first electrical interconnect shaft is configured to provide a positive current path and the second electrical interconnect shaft is configured to provide a negative current path to the electrically charged plates. A blind flange may be operatively associated with the first insulated body and with the vessel, with the blind flange including a first opening configured to receive the first electrical interconnect shaft and a second opening configured to receive the second electrical interconnect shaft. In one embodiment, the apparatus may further include a second insulated body (instead of the first insulated body) casted within the inner portion of the second housing and encapsulating the second electrical interconnect shaft, with the second insulated body including a polyurethane material. This apparatus may include a blind flange operatively associated with the first insulated body, the second insulated body, and the vessel, with the blind flange including a first opening configured to receive the first electrical interconnect shaft and a second opening configured to receive the second electrical interconnect shaft. The apparatus may include a first wire attached to the first electrical interconnect shaft and a first busbar connected to the first wire, the first busbar being operatively attached to a first segment of the electrically charged plates. Additionally, the apparatus may include a second wire attached to the second electrical interconnect shaft and a second busbar connected to the second wire, with the second busbar being operatively attached to a second segment of the electrically charged plates. The apparatus may also have a first boot and a second boot each configured to be placed over a portion of the first electrical interconnect shaft and the second electrical interconnect shaft, respectively. The boots may include a polyurethane composition. Additionally, the apparatus may include a first support member and a second support member each disposed within the internal portion of the vessel and operatively associated with the first and second segments of electrically charged plates. The first and second housings may each include a flange member. In one embodiment, the polyurethane material of the first and second insulated bodies has a characteristic hardness of between 70 and 90 and a dielectric strength greater than 5 kV/mm. The polyurethane material may also have a characteristic tension strength of between 1,000 psi and 3,000 psi and a BASHORE resilience percent of between 45 and 60%. The first and second insulated bodies may each be formed from a liquid polyurethane polymer solution having a viscosity of between 1,000 and 4,000 mPas.

A system for lowering viscosity of a hydrocarbon liquid is disclosed. The system includes: a vessel with an internal portion, the vessel containing the hydrocarbon liquid under pressure; a series of electrically charged plates within the internal portion, the electrically charged plates having a first segment and a second segment; a first electrical interconnect positioned within the internal portion of the vessel; a second electrical interconnect positioned within the internal portion of the vessel; and an insulated body encapsulating the first and second electrical interconnects, wherein the encapsulation includes casting a liquid polyurethane solution into a housing and allowing the liquid polyurethane solution to harden into the insulated body. The system may also include a blind flange operatively attached to the vessel, with the blind flange having a first opening configured to receive the first electrical interconnect and a second opening configured to receive the second electrical interconnect. A first wire may be attached to the first electrical interconnect and a first busbar may be connected to the first wire, with the first busbar being operatively attached to the first segment of the electrically charged plates. A second wire may be attached to the second electrical interconnect and a second busbar may be connected to the second wire, with the second busbar being operatively attached to the second segment of the electrically charged plates. A liner including an insulating material may line the internal portion of the vessel. The system may also include a first boot configured to be placed over a portion of the first electrical interconnect, with the first boot including a polyurethane composition. The system may also include a second boot configured to be placed over a portion of the second electrical interconnect, with the second boot including a polyurethane composition. The system may further include a first support member and a second support member each operatively attached with the first and second segments of the electrically charged plates.

In another embodiment, a system for lowering viscosity of a hydrocarbon liquid is disclosed. The system includes a treating vessel having a series of electrically charged plates, and wherein the treating vessel is under a pressure and containing the hydrocarbon liquid within an internal portion of the treating vessel, an electrical shaft connected to a bus positioned on the internal portion of the vessel, and a body including a polyurethane composition, wherein the polyurethane composition encapsulates the electrical shaft, and wherein the polyurethane body has a characteristic hardness of between 70 and 90 and a dielectric strength greater than 5 kV/mm. In one disclosed embodiment, the polyurethane body has a characteristic tension strength of between 1,000 psi and 3,000 psi and a BASHORE resilience percent of between 45 and 60%. Also, in one embodiment, the polyurethane body may be formed from a liquid polyurethane polymer solution having a viscosity of between 1,000 and 4,000 mPas.

In yet another embodiment, a process for providing an electrical current to a hydrocarbon liquid is disclosed. The process includes: providing a vessel containing the hydrocarbon liquid, wherein a series of charging plates are positioned within the vessel; providing a first flange housing and a second flange housing operatively associated with the vessel, wherein the first flange housing includes a first cavity and the second flange housing includes a second cavity, wherein the first and second cavities are operatively associated with a main cavity within the vessel; and providing a first electrical shaft within the first cavity and a second electrical shaft within the second cavity. The process also includes connecting a first electrical wire to the first electrical shaft, wherein the first electrical wire is positioned within the main cavity; connecting the first electrical wire to a first bus bracket within the main cavity; and casting a polyurethane composition in each of the first and second cavities and in a portion of the main cavity so that a liner body is formed. The process may further include attaching a blind flange onto the vessel, and providing an input electrical current through the first electrical shaft to the charging plates within the vessel. In one embodiment, the process further includes connecting a second electrical wire to the second electrical shaft, with the second electrical wire positioned within the main cavity; connecting the second electrical wire to a second bus bracket within the main cavity; and providing an outlet electrical current from the charging plates through the second electrical shaft. The first and second electrical shafts and the first and second electrical wires may each be embedded within the liner body. The electrical current may reduce a viscosity of the hydrocarbon liquid within the vessel. The first and second electrical shafts may each include ribs to increase a surface area for bonding with the polyurethane composition. In one embodiment, the polyurethane body has a characteristic hardness of between 70 and 90, a dielectric strength greater than 5 kV/mm, a characteristic tension strength of between 1,000 psi and 3,000 psi, and a BASHORE resilience percent of between 45 and 60%. Also, in one embodiment, a liquid polyurethane polymer solution is used to cast the polyurethane composition, and the liquid polyurethane polymer solution has a viscosity of between 1,000 and 4,000 mPas.

### BRIEF DESCRIPTION OF THE DRAWINGS

FIG. 1 is a flow chart illustration of the electrical delivery system of the present disclosure.

FIG. 2 is a flow chart illustration of the structural elements of one embodiment of the device herein disclosed.

FIG. 3 is a partial cutaway illustration of one of the embodiments of the electrical interconnect.

FIG. 4 is an exploded view of the electrical interconnect illustrated in FIG. 3.

FIG. 5 is a cross-sectional view of the electrical interconnect illustrated in FIG. 3.

FIG. 6 is a partial cutaway illustration of the electrical interconnect operatively associated with a blind flange member and a treating vessel.

FIG. 7A is a partial view illustration of one embodiment of the blind flange, electrical interconnect, plates and busbars.

FIG. 7B is an enlarged partial view of the plates and busbars in FIG. 7A.

FIG. 8 is a partial view illustration of one embodiment of the electrical interconnect, blind flange and busbars.

FIG. 9 is an exploded view of one embodiment of the treating vessel including the electrical interconnect.

FIG. 10 is an exploded view of one embodiment of the grid pack assembly.

FIG. 11A is a partial cutaway view of one embodiment depicting the plates within the treating vessel.

FIG. 11B is an enlarged view of the detail seen in FIG. 11A.

### DETAILED DESCRIPTION OF THE PREFERRED EMBODIMENTS

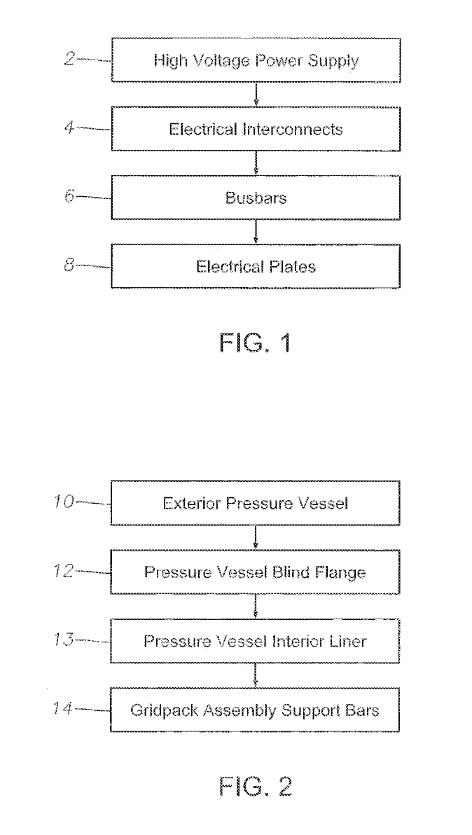

Referring now to FIG. 1, a flow chart illustration of the electrical delivery system to the apparatus of the present disclosure will now be described. In one embodiment, the system includes a high voltage power supply 2, such as a direct current source. In one preferred embodiment, the power supply is a commercially available DC power supply with operational power discharge range of 0-100 kV, and 0-100 mA. The power source 2 will be operatively connected to the electrical interconnects 4 (also referred to as electrodes) which in turn will be operatively connected to busbars 6. The electrical plates 8 will be operatively connected to the busbars 6. The system will be described in greater detail later in the disclosure.

FIG. 2 is a flow chart illustration of the structural elements of one embodiment of the device herein disclosed. More specifically, structural elements include the exterior pressure vessel 10, wherein the vessel 10 will be operatively connected to the blind flange 12. An interior liner 13 within the vessel 10 is included which in turn is operatively associated with a gridpack assembly support bars 14. The structural elements will be described in greater detail later in the disclosure.

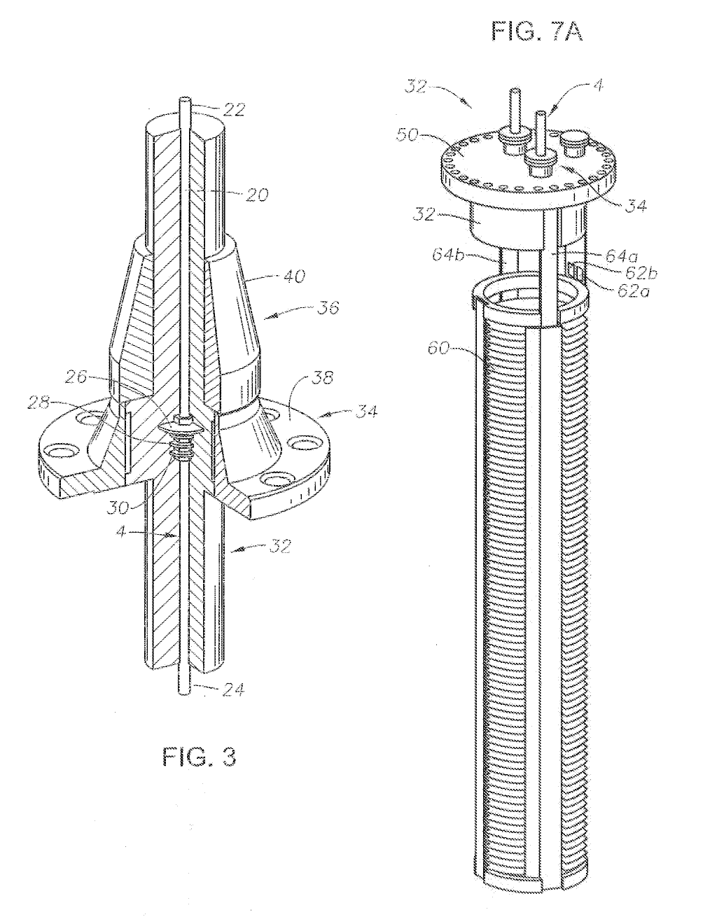

Referring now to FIG. 3, a partial cutaway illustration of one of the embodiments of the electrical interconnect 4 and housing 34 will now be described. It should be noted that like numbers appearing in the various figures refer to like components. The electrical interconnect 4 includes a shaft 20 that has a distal end 22 and a proximal end 24. The shaft 20 may be constructed of a metal such as steel or brass. The shaft includes a series of radially extending ribs, namely ribs 26, 28, 30. At least a portion of the shaft 20 will be encapsulated within an insulated body, wherein in one embodiment, the insulation body is a polyurethane. The polyurethane material is denoted at 32. The polyurethane material is commercially available from Axson Technologies under the name UR 3558. The insulation material is moldable (castable) and machinable insulation material with a high dielectric resistivity, chemical resistivity, physical strength (abrasion, tensile, modulus of elasticity, and suitable hardness) to withstand high voltage potentials and large forces generated by the pressure differential between the interior of the pressured assembly, and the atmospheric conditions. FIG. 3 also depicts the flange member, seen generally at 34 as well as the lower (upper) flange portion 36. The flange member 34 may also be referred to as housing 34. In one embodiment, the flange member 34 and the lower flange portion 36 will be constructed of a metal such as brass or steel. The flange member 34 will have a radial surface 38 that contains openings for nut and bolt connection purposes, as well understood by those of ordinary skill in the art. The lower flange portion 36 has a tapered surface 40 for sealingly engaging with the blind flange member as will be described later. As seen in FIG. 3, the polyurethane material 32 fills the inner portion of flange 34, wherein ribs 26, 28, 30 allow the engagement of the shaft 20 with the polyurethane material. In one embodiment, the liquid polyurethane polymer composition is poured into the inner flange so that the shaft 20 can be encapsulated within the cured polyurethane. The polyurethane polymer composition may have a characteristic hardness of between 70 and 90 and a dielectric strength greater than 5 kV/mm; a characteristic tension strength of between 1,000 psi and 3,000 psi and a BASHORE resilience percent of between 45 and 60% and a viscosity of between 1,000 and 4,000 mPa·s.

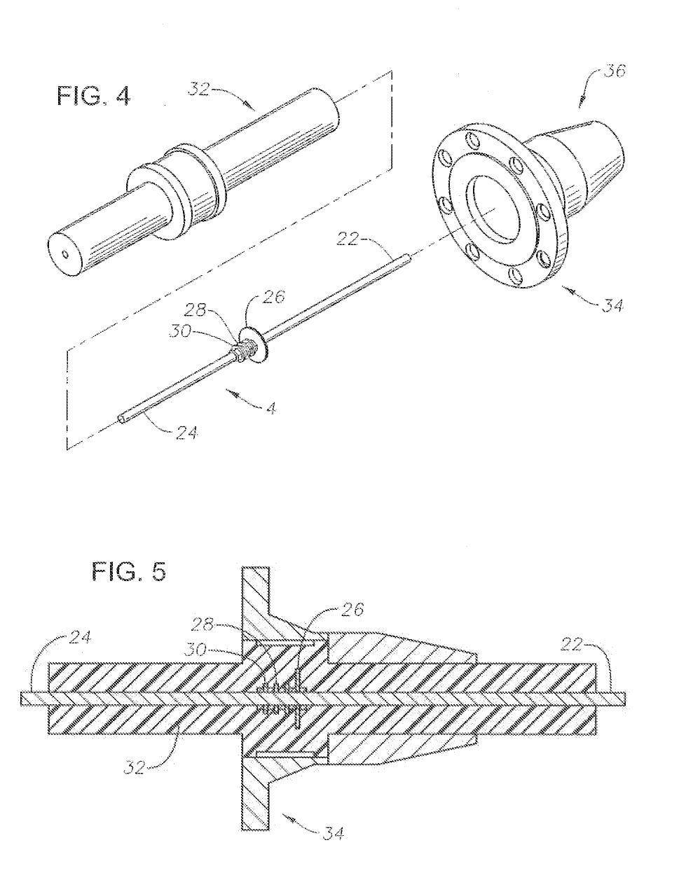

FIG. 4 is an exploded view of the electrical interconnect 4 and housing 34 illustrated in FIG. 3. As seen in FIG. 4, the polyurethane material 32 has a profile that is reciprocal to the inner portion of the flange member 34 since the polyurethane polymer composition is casted within the flange 34. Also, note that the ribs 26, 28, 30 are depicted. Referring now to FIG. 5, a cross-sectional view of the electrical interconnect 4 and housing 34 illustrated in FIGS. 3 and 4 will now be described. FIG. 5 shows the inner profile (also referred to as the main cavity) of the flange member 34. The electrical interconnect 4 and the ribs 26, 28, 30 are shown embedded in the polyurethane material.

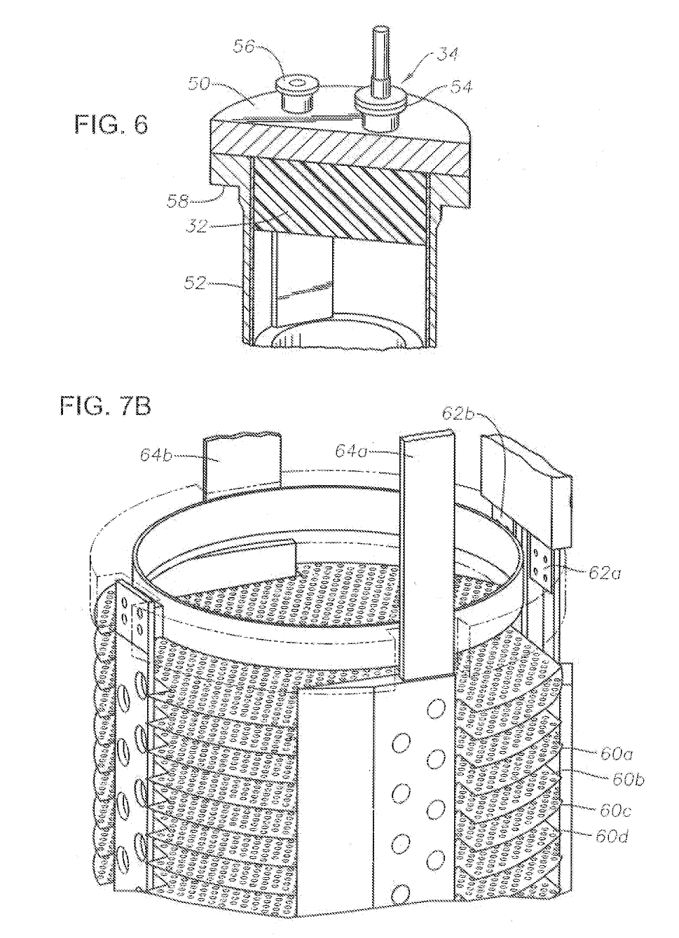

A partial cutaway illustration of the electrical interconnects operatively associated with the flange member 34, a blind flange 50 and a treating vessel 52 are shown in FIG. 6. The treating vessel 52 maintains the desired pressure and provides for the desired fluid flow velocity which provides for the proper residence time of the hydrocarbon liquid within the applied electric field. Thus, the flange member 34 is operatively connected to a reciprocal flange 54 of the blind flange 50. A second flange member (i.e. housing) 56 is depicted, wherein the second flange member 56 is for the placement of a second electrical interconnect and reciprocal flange member as will be more fully described later in the application. FIG. 6 also depicts the polyurethane material 32. Note that the blind flange 50 is operatively connected to the treating vessel 52 via vessel flange 58 of the treating vessel 52, as well understood by those of ordinary skill in the art. The blind flange 50 allows the sealing of pressure contained within the vessel 52, housing of the electrical interconnects (i.e. electrodes) and provides access to the internal components housed therein to facilitate the ease of assembly and disassembly of the vessel 52 and its internal components.

Referring now to FIG. 7A, a partial view illustration of one embodiment of the blind flange 50, electrical interconnect 4, series of stacked plates seen generally at 60, bus bars 62a, 62b, and support members 64a, 64b. In the view of FIG. 7A, the support members 64a, 64b run the length of the internal portion of the treating vessel 52 and wherein the series of plates 60, which in one embodiment is a series of plates which have openings therein, are connected for support to the support member 64a, 64b. The busbars 62a, 62b are electrically connected to wires from the electrical interconnect (not seen in this view) and the busbars 62a, 62b are also operatively connected to the plates 60; hence, half the plates (the first segment) are electrically connected to the busbar 62a for a positive current flow and the other half of the plates (the second segment) are electrically connected to the busbar 62b for a negative current flow.

FIG. 7B is an enlarged view of the detail seen in FIG. 7A. FIG. 7B depicts the support member 64a, 64b along with the busbars 62a, 62b. The series of electrical plates 60 are shown; for instance individual plates 60a, 60b, 60c, 60d are depicted in FIG. 7B where alternating plates 60a, 60c are connected to the busbar 62a, while plates 60b, 60d are connected to the busbar 62b. One set of alternating plates is referred to as the first segment, and the other set of alternating plates are referred to as the second segment. The plates are separated and alternately charged to deliver the appropriate electric field for a specified time. Note that the plates have openings therein for the flow of fluid, wherein the hydrocarbon fluid within the vessel is exposed to an electric field for purposes of viscosity reduction while moving through the vessel.

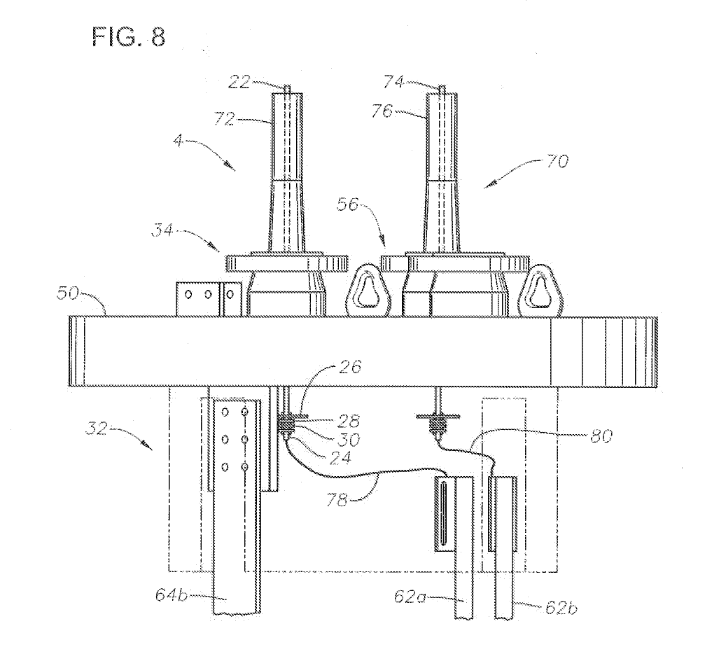

Referring now to FIG. 8, a partial view illustration of one embodiment of the electrical interconnect, blind flange and busbars will now be described. More specifically, FIG. 8 depicts the electrical interconnect 4 along with the associated flange member 34, as well as the electrical interconnect 70 and the associated flange member 56. The shaft distal end 22 is covered by an electrical boot 72, also referred as an insulation boot 72. The shaft proximal end 24 is depicted embedded in the polyurethane material 32. An electrical interconnect shaft 74 is shown operatively associated with the flange member 56, and wherein the shaft 74 is partially covered by the electrical boot 76. In one embodiment, the boots 72, 76 comprise the polyurethane composition. FIG. 8 further depicts the wire 78 which is connected at one end to the proximal end 24 of shaft and at the other end to the busbar 62a which provides for an electrical path to half the plates i.e. the first segment of the plates 60. The wire 80 is connected at one proximal end of the shaft 74 and at the other end to the busbar 62b which provides for an electrical path to the other half of the plates i.e. the second segment of the plates 60. The blind flange 50 is also illustrated, wherein the blind flange 50 will be attached to the vessel as previously noted.

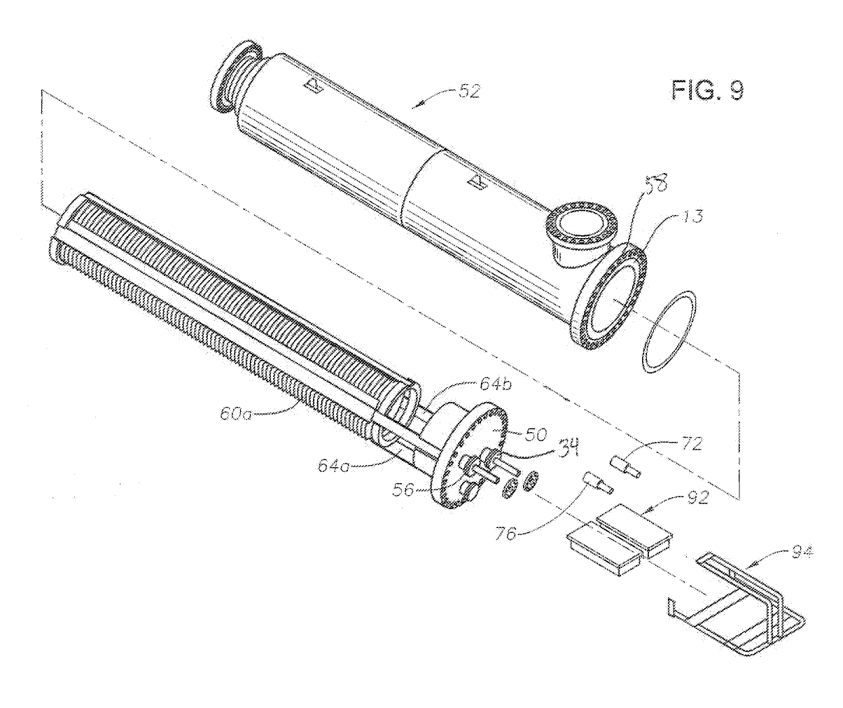

FIG. 9 is an exploded view of one embodiment of the treating vessel 52 including the electrical interconnects. As illustrated in FIG. 9, the treating vessel 52 has disposed therein the internal vessel liner 13, wherein the material of the internal vessel liner 13 may be a polyurethane similar in composition and characteristics of the polyurethane compositions previously mentioned. It should be noted that other dielectric materials are available such as Teflon, PTFE, and materials of similar durometer and dielectric strength The liner 13 electrically insulates the internal components from the exterior vessel 52 and blind flange 50. In addition, the liner 13 isolates third party cathodic protection systems from the charged electric plates 60.

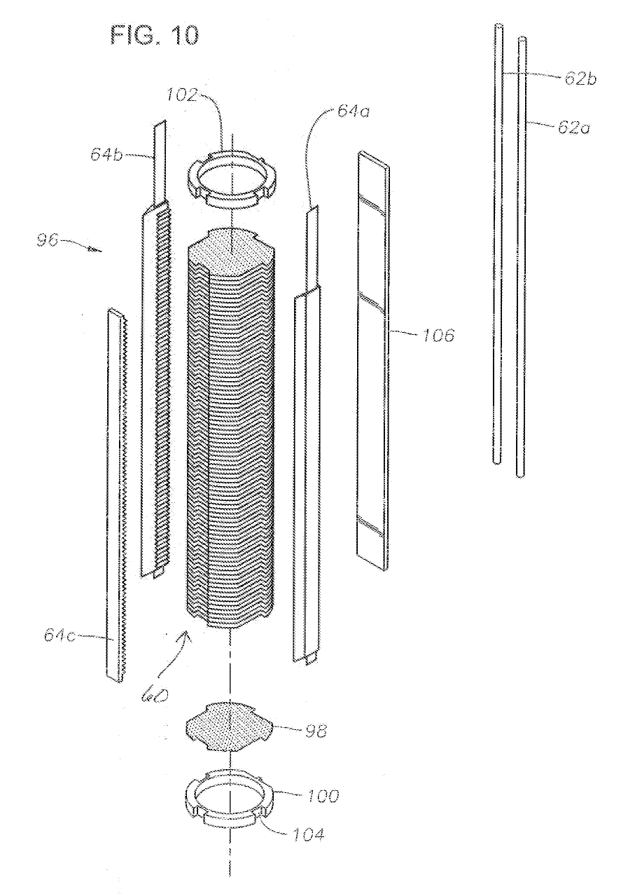

FIG. 9 also depicts the electrically chargeable plates, such as plate 60a. The series of stacked plates are referred to as plates 60. Disposed about the plates 60 will be the support members 64a, 64b, which are configured to support the plates 60 within the vessel 52. Also, the busbars 62a, 62b are shown in FIG. 10. The blind flange assembly is shown, which includes the blind flange 50, the first flange member 34, the second flange member 56, and the electrical boot members 72, 76. In the embodiment seen in FIG. 9, washers and collars are provided in order to establish a seal for the vessel 52 with flanges 50, 58 since the internal portion of the vessel 52 will be under significant pressures and temperatures. Also illustrated in FIG. 9 is the exterior electrical junction box 92, wherein the exterior electrical junction box safety cage 94 surrounds the junction box 92.

Referring now to FIG. 10, an exploded view of one embodiment of the grid pack assembly 96 will now be described. The grid pack assembly 96 includes the plates 60 which comprises the first and second segment of the plates along with the load bearing support members 64a, 64b, 64c and the busbars 62a, 62b. The individual plate 98 is shown along with the lower end collar 100 and upper end collar 102 for containment of the plates 60. Note that the collars and the plates 60 contain recesses, such as recess 104, for placement of the support members and/or busbars. The support bars 64a, 64b, 64c also hold the plates 60 at a specific separation interval. The busbars 62a, 62b electrically connect the power supply via the electrical interconnects (i.e. electrodes), in order to deliver the electric field. The view of FIG. 10 also depicts the busbars 62a, 62b, and wherein the busbars 62a, 62b will be encased within a dielectric insulating component 106, which may be a polyurethane composition as previously disclosed.

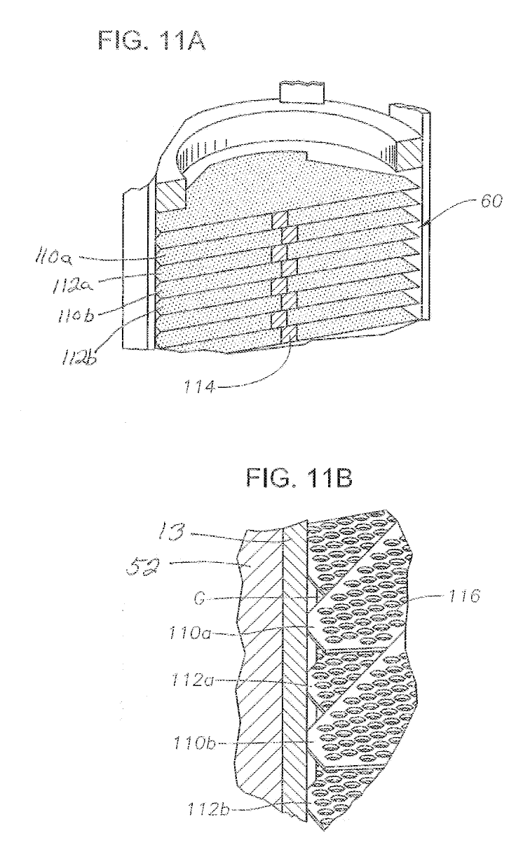

FIG. 11A is a partial cutaway view of one embodiment depicting some of the plates 60 within the treating vessel 52. As noted earlier, the series of plates 60 will be stacked one on top of the other in one embodiment. Additionally, in an alternating sequence, one segment of plates 60 will be attached to the busbar 62a, and the second segment of plates will be attached to the busbar 62b. For instance, the plates 110a, 110b will be attached to busbar 62a and will carry a positive (input) charge, while plates 112a, 112b will be attached to the busbar 62b and will carry a negative (output) charge thereby creating an electric field within the vessel. FIG. 11A also depicts the attachment spacers, such as attachment spacer 114. The attachment spacer 114 serves to attach the plates together in series as well as providing a predetermined space between individual plates. FIG. 11B is an enlarged view of the detail seen in FIG. 11A. FIG. 11B illustrates the plates 110a, 110b, 112a, 112b, wherein flow openings are depicted through the plates, such as opening 116. The openings (such as opening 116) and spacing (distance between plates) allow sufficient fluid flow through the plates with sufficiently low back pressure while allowing sufficient time for exposure of the fluid to the applied electric field. The gap “G” prevents sediment buildup i.e. prevents sediment accumulation on interior surface walls which in turn allows for self-cleaning interior walls, by allowing a clearance for the material (oil flow) to pass.

In one embodiment, the three structural support members 64a, 64b, 64c are to be electrically-neutral and electrically insulated to allow structural rigidity of the plates 60, preventing unwanted fluid bypass around the plates, and prevent parasitic electrical current loss. In one preferred embodiment, the support members 64a, 64b, 64c are surrounded by a casted polyurethane insulation layer of sufficient thickness with holes drilled through at a common interval of suitable separation to physically attach each plate indicated above a common bolt assembly, while retaining electrical isolation of each plate.

An aspect of the present disclosure includes the disclosed apparatus encases a high voltage electrical interconnect allowing the electrode shaft to transfer power from a high voltage junction box into a pressure vessel. Another aspect is that the polyurethane is molded into the assembly, surrounding and insulating the electrical shaft from shorting to the vessel wall. Another aspect is that the electrical shaft may be made of threaded brass or steel rod in one embodiment, with a pattern of ribs, allowing it to anchor within the polyurethane mold. In yet another embodiment, the pressure vessel is fitted with a flange on one side to connect to the pressure vessel, and is threaded to connect to the electrical junction box on the other side.

Although the present invention has been described in considerable detail with reference to certain preferred versions thereof, other versions are possible. Therefore, the spirit and scope of the appended claims should not be limited to the description of the preferred versions contained herein.

What is claimed is:

1. An apparatus for transmitting an electrical current through a vessel, said vessel having a series of electrically charged plates within an internal portion, wherein said vessel being under a pressure and containing a hydrocarbon liquid within the internal portion, the apparatus comprising:
a first housing having an inner portion operatively associated with the vessel;
a first electrical interconnect shaft positioned within the first housing;
a first insulated body casted within the inner portion of the first housing, the first electrical interconnect shaft being embedded within the first insulated body, the first insulated body comprising a polyurethane material.

2. The apparatus of claim 1 further comprising:
a second housing having an inner portion operatively associated with the vessel;
a second electrical interconnect shaft positioned within the second housing, wherein the first insulated body is casted within the inner portion of the second housing and the second electrical interconnect shaft is embedded within the first insulated body, and wherein the first electrical interconnect shaft is configured to provide a positive current path and the second electrical interconnect shaft is configured to provide a negative current path to the electrically charged plates.

3. The apparatus of claim 2 further comprising a blind flange operatively associated with the first insulated body and with the vessel, the blind flange having a first opening configured to receive the first electrical interconnect shaft and a second opening configured to receive the second electrical interconnect shaft.

4. The apparatus of claim 1 further comprising:
a second housing having an inner portion operatively associated with the vessel;
a second electrical interconnect shaft positioned within the second housing;
a second insulated body casted within the inner portion of the second housing, the second electrical interconnect shaft being embedded within the second insulated body, the second insulated body comprising the polyurethane material, and wherein the first electrical interconnect shaft is configured to provide a positive current path and the second electrical interconnect shaft is configured to provide a negative current path to the electrically charged plates.

5. The apparatus of claim 4 further comprising a blind flange operatively associated with the first insulated body, the second insulated body, and the vessel, wherein the blind flange has a first opening configured to receive the first electrical interconnect shaft and a second opening configured to receive the second electrical interconnect shaft.

6. The apparatus of claim 5 further comprising:
a first wire attached to the first electrical interconnect shaft;
a first busbar connected to the first wire, the first busbar being operatively attached to a first segment of the electrically charged plates.

7. The apparatus of claim 6 further comprising:
a second wire attached to the second electrical interconnect shaft;
a second busbar connected to the second wire, the second busbar being operatively attached to a second segment of the electrically charged plates.

8. The apparatus of claim 7 further comprising a first boot configured to be placed over a portion of the first electrical interconnect shaft, the first boot comprising a polyurethane composition.

9. The apparatus of claim 8 further comprising a second boot configured to be placed over a portion of the second electrical interconnect shaft, the second boot comprising a polyurethane composition.

10. The apparatus of claim 9 further comprising a first support member disposed within the internal portion of the vessel and operatively associated with the first and second segments of the electrically charged plates.

11. The apparatus of claim 10 further comprising a second support member disposed within the internal portion of the vessel and operatively associated with the first and second segments of the electrically charged plates.

12. The apparatus of claim 4 wherein the first housing and the second housing each includes a flange member.

13. The apparatus of claim 4 wherein the polyurethane material of the first and second insulated bodies has a characteristic hardness of between 70 and 90, and a dielectric strength greater than 5 kV/mm.

14. The electric interconnect of claim 13 wherein the polyurethane material of the first and second insulated bodies has a characteristic tension strength of between 1,000 psi and 3,000 psi and a BASHORE resilience percent of between 45 and 60%.

15. The electric interconnect of claim 14 wherein the first and second insulated bodies are each formed from a liquid polyurethane polymer solution having a viscosity of between 1,000 and 4,000 mPas.

16. A system for lowering viscosity of a hydrocarbon liquid, the system comprising:
a vessel with an internal portion, the vessel containing the hydrocarbon liquid under pressure;
a series of electrically charged plates within the internal portion, the electrically charged plates having a first segment and a second segment;
a first electrical interconnect positioned within the internal portion of the vessel;
a second electrical interconnect positioned within the internal portion of the vessel;
an insulated body encapsulating the first and second electrical interconnects, wherein the encapsulation includes casting a liquid polyurethane solution into a housing and allowing the liquid polyurethane solution to harden into the insulated body;
a blind flange operatively attached to the vessel, the blind flange having a first opening configured to receive the first electrical interconnect and a second opening configured to receive the second electrical interconnect.

17. The apparatus of claim 16 further comprising:
a first wire attached to the first electrical interconnect;
a first busbar connected to the first wire, the first busbar being operatively attached to the first segment of the electrically charged plates.

18. The system of claim 17 further comprising:
a second wire attached to the second electrical interconnect;
a second busbar connected to the second wire, the second busbar operatively attached to the second segment of the electrically charged plates.

19. The system of claim 18 further comprising a liner lining the internal portion of the vessel, the liner comprising an insulating material.

20. The system of claim 19 further comprising a first boot configured to be placed over a portion of the first electrical interconnect, the first boot comprising a polyurethane composition.

21. The system of claim 20 further comprising a second boot configured to be placed over a portion of the second electrical interconnect, the second boot comprising a polyurethane composition.

22. The system of claim 21 further comprising a first support member operatively attached with the first and second segments of the electrically charged plates.

23. The system of claim 22 further comprising a second support member operatively attached with the first and second segments of the electrically charged plates.

24. A system for lowering viscosity of a hydrocarbon liquid, the system comprising:
a treating vessel having a series of electrically charged plates, wherein the treating vessel is under a pressure and contains the hydrocarbon liquid within an internal portion of the treating vessel;
an electrical shaft connected to a bus positioned on the internal portion of the vessel;
a body comprising a polyurethane composition, the polyurethane composition encapsulating the electrical shaft, wherein the polyurethane body has a characteristic hardness of between 70 and 90 and a dielectric strength greater than 5 kV/mm.

25. The apparatus of claim 24 wherein the polyurethane body has a characteristic tension strength of between 1,000 psi and 3,000 psi and a BASHORE resilience percent of between 45 and 60%.

26. The apparatus of claim 25 wherein the polyurethane body is formed from a liquid polyurethane polymer solution having a viscosity of between 1,000 and 4,000 mPas.

27. A process for providing an electrical current to a hydrocarbon liquid, the process comprising the steps of:
a) providing a vessel containing the hydrocarbon liquid, wherein a series of charging plates are positioned within the vessel;
b) providing a first flange housing and a second flange housing operatively associated with the vessel, wherein the first flange housing includes a first cavity and the second flange housing includes a second cavity, wherein the first and second cavities are operatively associated with a main cavity within the vessel;
c) providing a first electrical shaft within the first cavity;
d) providing a second electrical shaft within the second cavity;
e) connecting a first electrical wire to the first electrical shaft, wherein the first electrical wire is positioned within the main cavity;
f) connecting the first electrical wire to a first bus bracket within the main cavity;
g) casting a polyurethane composition in each of the first and second cavities and in a portion of the main cavity so that a liner body is formed;
h) attaching a blind flange onto the vessel; and
i) providing an input electrical current through the first electrical shaft to the charging plates within the vessel.

28. The process of claim 27 further comprising the steps of:
e1) connecting a second electrical wire to the second electrical shaft, wherein the second electrical wire is positioned within the main cavity;
f1) connecting the second electrical wire to a second bus bracket within the main cavity; and
j) providing an output electrical current from the charging plates through the second electrical shaft.

29. The process of claim 28 wherein the first and second electrical shafts and the first and second electrical wires are each embedded within the liner body formed in step (g).

30. The process of claim 29 wherein the electrical current reduces a viscosity of the hydrocarbon liquid within the vessel.

31. The process of claim 30 wherein the first and second electrical shafts each includes ribs to increase a surface area for bonding with the polyurethane composition.

32. The process of claim 31 wherein the liner body has a characteristic hardness of between 70 and 90 and a dielectric strength greater than 5 kV/mm.

33. The process of claim 32 wherein the liner body has a characteristic tension strength of between 1,000 psi and 3,000 psi and a BASHORE resilience percent of between 45 and 60%.

34. The process of claim 33 wherein a liquid polyurethane polymer solution is used to cast the polyurethane composition in step (g), and wherein the liquid polyurethane polymer solution has a viscosity of between 1,000 and 4,000 mPas.
